(19) United States
(12) Patent Application Publication
(10) Pub. No.: US 2014/0268610 A1
(43) Pub. Date: Sep. 18, 2014

(54) METHOD AND SYSTEM FOR FORMING A MICROVIA IN A PRINTED CIRCUIT BOARD

(71) Applicant: Gregory HALVORSON, Santa Clara, CA (US)

(72) Inventor: Gregory HALVORSON, Santa Clara, CA (US)

(21) Appl. No.: 13/833,840

(22) Filed: Mar. 15, 2013

(51) Int. Cl. H05K 3/46; H05K 1/02

(52) U.S. Cl. CPC H05K 3/4623; H05K 1/0298
USPC 361/765; 361/772; 29/846

(57) ABSTRACT

A method for forming vias in a multilayered printed circuit board is disclosed, which includes providing a multilayered printed circuit board having at least two or more layers; placing a donut pad on an upper layer of at least one layer of the multilayered printed circuit board for forming a via through one or more of the layers of the multilayered printed circuit board, the donut pad having a clearance of less than approximately 80 to 90 percent of a diameter of the via; and forming at least one via through the donut pad and at least one or more layers of the multilayered printed circuit board.

### FIELD OF THE INVENTION

This invention relates to a method and system for forming a via in a printed circuit board, and more particularly, a method and system for forming or creating one or more microvias using a donut pad in a printed circuit board having three or more layers.

### BACKGROUND

Printed circuit boards (PCBs) are used in virtually all electronic devices. Generally, a printed circuit board can be used to mechanically support and electrically connect electronic components using conductive pathways, tracks or signal traces etched from copper sheets laminated onto a non-conductive substrate or added using an additive process. Once the printed circuit board is populated with electronic components, the printed circuit board is often referred to as a printed circuit assembly (PCA), or a printed circuit board assembly, PCB Assembly (PCBA).

Circuit substrates for multilayered printed circuit boards can be formed by stacking several dielectric layers and several patterned circuit layers alternately. The patterned circuit layers are defined by lithography and etching a copper layer or an additive process using lithography as well. The dielectric layers are disposed between the patterned circuit layers for protecting and separating the patterned circuit layers. The patterned circuit layers are electrically connected to each other through conductive vias in the dielectric layers. Furthermore, several contacts are formed on surfaces of the circuit substrates for electrically connecting with an outer electronic device.

A conventional circuit substrate can include a core layer, a patterned circuit layer, a dielectric layer and at least a conductive via. The patterned circuit layer is disposed between the core layer and the dielectric layer and includes at least one capture pad, which is made of copper. The conductive via penetrates the dielectric layer and contacts the capture pad.

In the conventional circuit substrate, the method for fabricating the conductive via includes forming the via by penetrating the dielectric layer using a laser drilling or evaporation method. The via exposes the capture pad, and an electroless copper layer composed of sub-micro level copper particles is formed on the capture pad and an inner wall of the via through an electroless plating process. An electroplated copper layer is then formed on the electroless copper layer by an electroplating process. The entire via is then filled with the electroplated copper layer.

Although the capture pad, the electroless copper layer and the electroplated copper layer are all made of copper in the above circuit substrate, all of them have different microstructures. For example, the electroless copper layer made of sub-micro level copper particles has less strength. If the formation of the via is poor, the electrical connection between the conductive via and the patterned circuit layer can fail.

Accordingly, it would be desirable to a method and system for forming one or more vias in a printed circuit board, and more particularly, a method and system for creating one or more microvias in a printed circuit board having three or more layers using a donut pad without burning through, for example, the copper capture pad layer and having a via structure that encompasses the edge to edge clearance of the donut pad while maintaining acceptable geometry.

### SUMMARY OF THE INVENTION

In consideration of the above issues, it would be desirable to have a method and system, which provides for microvia formation in a printed circuit board.

In accordance with an embodiment, a method for forming vias in a multilayered printed circuit board is disclosed, comprising: providing a multilayered printed circuit board having at least two or more layers; placing a donut pad on an upper layer of at least one layer of the multilayered printed circuit board for forming a via through one or more of the layers of the multilayered printed circuit board, the donut pad having a clearance of less than approximately 80 to 90 percent of a diameter of the via; and forming at least one via through the donut pad and at least one or more layers of the multilayered printed circuit board.

In accordance with another embodiment, a method for forming vias in a multilayered printed circuit board is disclosed, comprising: providing a multilayered printed circuit board comprising at least three dielectric layers, and at least two patterned circuit layer, and wherein each of the at least two patterned circuit layers are disposed between a pair of dielectric layers, and wherein at least one of the patterned circuit layers includes at least one capture pad; placing a donut pad on an upper layer of at least of the patterned circuit layers; and forming at least one via through the donut pad and a dielectric layer to the at least one capture pad; wherein the donut pad has a clearance of less than approximately 80 to 90 percent of a diameter of the at least one via.

In accordance with a further embodiment, a printed circuit board is disclosed formed by the following process: providing a multilayered printed circuit board comprising at least three dielectric layers, and at least two patterned circuit layer, and wherein each of the at least two patterned circuit layers are disposed between a pair of dielectric layers, and wherein at least one of the patterned circuit layers includes at least one capture pad; placing a donut pad on an upper layer of at least of the patterned circuit layers; and forming at least one via through the donut pad and a dielectric layer to the at least one capture pad; wherein the donut pad having a clearance of less than approximately 80 to 90 percent of a diameter of the via.

In accordance with another exemplary embodiment, the donut pad has a clearance of approximately 60 percent or less of the diameter of via.

In accordance with a further exemplary embodiment, the multilayered printed circuit board comprises a multilayered laminate formed by the steps of: providing at least one two-sided copper-clad laminate; etching circuitry on each of the two-sides of the at least one two-sided copper-clad laminate; placing the donut pad on an upper layer of the at least one two-sided copper-clad laminate; placing a copper capture pad on a lower layer of the at least one two-sided copper-clad laminate; laminating a top and a bottom prepreg layer on the two-sided copper-clad laminate; and laminating a copper foil layer on the top and bottom prepreg layers.

In accordance with another exemplary embodiment, the method includes forming the at least one via in the multilayered printed circuit board after lamination; forming an electroless copper layer on the capture pad and an inner wall of the at least one via; forming an electroplated copper layer on the capture pad and the inner wall of the at least one via; and filling the at least one via with copper.

It is to be understood that both the foregoing general description and the following detailed description are exemplary and explanatory and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is an illustration of a lamination of a multilayer printed circuit board in accordance with an exemplary embodiment;

FIG. 2 is an illustration of a donut or donut pad on an upper layer of a two-sided copper-clad laminate of a multilayered printed circuit board before forming a via in the lamination of the multilayer printed circuit board in accordance with an exemplary embodiment;

FIGS. 3A-3D are a series of photographs for a pad in accordance with an exemplary embodiment;

FIGS. 4A-4D are a series of photographs for a donut pad having a clearance of 0.0045 inches in accordance with an exemplary embodiment;

FIGS. 5A-5D are a series of photographs for a donut pad having a clearance of 0.0040 inches in accordance with an exemplary embodiment;

FIGS. 6A-6D are a series of photographs for a donut pad having a clearance of 0.0035 inches in accordance with an exemplary embodiment; and

FIGS. 7A-7D are a series of photographs for a donut pad having a clearance of 0.0030 inches in accordance with an exemplary embodiment.

### DESCRIPTION OF THE PREFERRED EMBODIMENTS

Reference will now be made in detail to the embodiments of the invention, examples of which are illustrated in the accompanying drawings. Wherever possible, the same reference numbers are used in the drawings and the description to refer to the same or like parts.

As set forth above, a printed circuit board is configured to mechanically support and electrically connect electronic components using conductive pathways, tracks or signal traces etched from copper sheets laminated onto a non-conductive substrate. Typically, the two processing methods, which are used to produce a double-sided PCB with plated through holes include a subtractive methods that removes copper from an entirely copper-coated board, and additive process, which adds desired copper traces to an insulating substrate. Subtractive methods can for example, include a silk screen printing, which uses etch-resistant inks to protect the copper foil and a subsequent etching process to remove unwanted copper. Alternatively, the inks can be conductive, and/or printed on a blank (non-conductive) board, which can be used to form a through hole or via. Another example of a subtractive method is photoengraving, which uses a photomask and developer to selectively remove a photoresist coating. The remaining photoresist protects the copper foil, and a subsequent etching process removes the unwanted copper. For example, the photomask can be prepared with a photoplotter from data produced by a technician using CAM, or computer-aided manufacturing software.

Alternatively, additive processes add a copper traces to an insulating substrate. In the full additive process the bare laminate is covered with a photosensitive film which is imaged, for example exposed to light though a mask and then developed which removes the unexposed film. The laminate is then plated with copper in the sensitized areas. When the mask is stripped, a finished PCB is produced.

The most common is a semi-additive process, wherein the unpatterned board has a thin layer of copper already, and applying a reverse mask to the thin layer copper. Unlike a subtractive process mask, this mask exposes those parts of the substrate that will eventually become the traces. Additional copper is then plated onto the board in the unmasked areas, which can be plated to a desired weight. The mask is then stripped away and a brief etching step removes the now-exposed bare original copper laminate from the board, isolating the individual traces.

The additive process is commonly used for multilayer boards as it facilitates the plating-through of the holes to produce conductive vias in the circuit board. Each trace consists of a flat, narrow part of the copper foil that remains after etching. The resistance, determined by width and thickness, of the traces must be sufficiently low for the current the conductor will carry. Power and ground traces may need to be wider than signal traces. In a multilayer board, for example, one entire layer may be mostly solid copper to act as a ground plane for shielding and power return.

Chemical etching, for example, can be done with ammonium persulfate, cupric chloride (or copper(II) chloride), and/or ferric chloride. For example, for plated-through holes, additional steps of electroless deposition are done after the holes are drilled, then copper is electroplated to build up the thickness, the boards are screened, and plated with tin/lead. The tin/lead becomes the resist leaving the bare copper to be etched away.

Holes or vias can be drilled through the PCB with small-diameter drill bits made of, for example, solid coated tungsten carbide. Once the holes are laser drilled, for example, by YAG (Yttrium Aluminum Garnet), CO₂, and/or a UV laser process, the holes can be filled with annular rings or hollow rivets to create vias. The vias allow the electrical and thermal connection of conductors on opposite sides of the PCB. In addition, when small vias are required, the vias may be evaporated by lasers to form microvias.

After the printed circuit board (PCB) is completed, electronic components can be attached to form a functional printed circuit assembly or a printed circuit board assembly. In through-hole construction, component leads are inserted in holes. In surface-mount construction, the components are placed on pads or lands on the outer surfaces of the PCB. In accordance with an exemplary embodiment, component leads are electrically and mechanically fixed to the board with a molten metal solder.

In accordance with an exemplary embodiment, a method for forming vias in a multilayered printed circuit board is disclosed, which includes providing a multilayer printed circuit board having at least two or more layers; placing a donut pad on an upper layer of the multilayered printed circuit board for forming a via through one or more of the layers of the multilayer printed circuit board, the donut pad having an inner diameter of less than approximately 80 to 90 percent of a diameter of the via, and more preferably 60 percent of a diameter of the via; and forming at least one via through the donut pad and at least one or more layers of the multilayered printed circuit board.

In accordance with an exemplary embodiment, it would be desirable to have a method and/or process that allows microvia formation through at least three layers of a multilayered printed circuit board without burning through the copper capture pad layer, for example, a half ounce copper capture pad.

In accordance with an exemplary embodiment, a 4 layer printed circuit board process from cam (computer-aided manufacturing) through plating is disclosed. In accordance with an exemplary embodiment, the method comprising; providing at least one two-sided copper-clad laminate having at least one copper donut pad on an upper surface thereof and a copper capture pad on a lower surface thereof; etching circuitry on each of the two-sides of the at least one two-sided copper-clad laminate; laminating a top and a bottom prepreg layer on the two-sided copper-clad laminate; and laminating a copper foil layer on the top and bottom prepreg layer. The step of performing the laminating of the multilayered printed circuit board by placing the two-sided laminate, the top and bottom prepreg layer and the copper foils layers in a press and applying pressure and heat for a period of time.

In accordance with an exemplary embodiment, a multilayer laminate 100 is shown in FIG. 1. The multilayered laminate 100 includes a two-sided copper-clad laminate 110, which is etched to include circuitry on both sides, and then a laminate of a dielectric layer (or prepreg) 120 and a copper foil 130 is placed on an upper surface (or top layer) 112 and a lower surface (or bottom layer) 114 of the two-sided copper clap laminate 110, respectively. The multilayered laminate 100 also includes one or more copper capture pads 140 and at least one donut pad 150. The one or more capture pads 140 are preferably made of copper and each define a lower surface of a conductive via. In addition, one or more copper donut pads 200 can be placed on an upper surface 112 of the two sided copper-clad laminate 110. The lamination of the laminate of dielectric layer or prepreg 120 and copper foil 130 to the two-sided copper-clad laminate 110 can be performed by placing the stack of materials in a press and applying pressure and heat for a period of time, and produces an inseparable one piece product.

For example, the dielectric layer 120 can be a pre-preg layer, which can be any type of pre-impregnated composite fibres where a material, such as epoxy is already present as used for printed circuit boards. For example, the pre-preg layer can take the form of a weave or are uni-directional. In addition, the pre-preg layer can contain an amount of the matrix material used to bond them together and to other components during manufacture.

In accordance with an exemplary embodiment, a pad or donut pad 150 as shown in FIG. 2, is applied to an upper layer 112 of the two-sided laminate 110 to assist with the forming (or drilling) of the vias and provide an upper surface of the conductive via. The donut pad 150 is preferably placed on an upper layer 112 of the two-sided laminate 110 for forming a via through one or more of the layers of the multilayered printed circuit board. In accordance with an exemplary embodiment, the donut pad 150 has a clearance or inner diameter 152 of less than approximately 80 percent of a diameter of the via, and more preferably less than 60 percent of a diameter of the via. In accordance with an exemplary embodiment, at least one via is drilled or laser through the donut pad 150 and at least one or more layers of the multilayered laminate 110.

In accordance with an exemplary embodiment, a computer aided manufacturing process was performed using a pad or donut pad 150 as shown in FIG. 2, each of the donut pads 150 having the following outer diameter 154 and clearances or inner diameters 152:

| | Outer diameter (154)/Clearance (152) |
|---|---|
| Type 1 | 0.008 in. × 0.000 (Solid Pad) |
| Type 2 | 0.008 in. × 0.00450 in. |
| Type 3 | 0.008 in. × 0.00400 in. |
| Type 4 | 0.008 in. × 0.00035 in. |
| Type 5 | 0.008 in. × 0.00300 in. |

In accordance with an exemplary embodiment, the multilayered laminate 100 can be prepared by performing an inner-layer preparation through oxide using a 0.002 H/H process. In accordance with an exemplary embodiment, the multilayered laminate 100 can have a thicker dielectric with different copper thicknesses as well. In accordance with an exemplary embodiment, for example, as shown in FIG. 1, the multilayered lamination can include a copper foil (H) 130, a prepreg (1×106, 370HR) 120, a laminate (0.002 H/H, 370HR) 110, a prepreg (1×106 370HR) 120, and a copper foil (H) 130. In accordance with an exemplary embodiment, different materials can be used for the prepreg and/or laminate as disclosed in IPC-4101. A pad or donut pad 150 as described above, can be placed onto an upper surface 112 of the laminate 110 and in accordance with an exemplary embodiment, a 5 mil laser forming was performed to burn through the first two layer of copper (layers 1 and 2) while stopping at layer 3 (copper capture pad) without burning though the capture pad. In accordance with an exemplary embodiment, the laser can be a YAG laser, a CO₂ laser, a UV laser and/or a carbide drill.

In accordance with an exemplary embodiment, after forming the at least one via, a light hand sanding for deburring was performed, and the one or more vias on the multilayered printed circuit board can be processed through standard electroless copper. The via can then be coated with an outer layer through a barrel plate image, and then filled with an electroplated copper layer. In accordance with en exemplary embodiment, a micro-section of the laser vias for evaluation was performed and is shown in FIGS. 3-7.

In accordance with an exemplary embodiment, as shown in FIGS. 3-7, the best via formation process was achieved with the pad having the smallest clearance (See FIG. 7). In accordance with an exemplary embodiment, the via formation using the donut pad having a clearance 152 of 0.003 inches for a 5 mil laser drill hole allowed a connection between layer 1 to layer 3 without compromising the geometry of the microvia. In accordance with another exemplary embodiment, a solid donut pad having no clearance produced the next best microvia geometry with a strong connection to layer 2.

In accordance with an exemplary embodiment, for a donut pad, the clearance of the donut pad is preferably at least 80 percent smaller than a diameter of the laser drill (i.e., microvia), more preferably at least 70 percent smaller than the diameter of the microvia, and most preferably at least 60 percent smaller than the diameter of the microvia. For example, for a microvia of 0.005 inches formed by laser evaporation or drilling, the clearance of the donut pad can be 0.004, more preferably 0.0035 inches, and most preferably 0.003 inches or less.

It can be appreciated that the method and processes as disclosed herein are not limited to the formation of microvia formation through 3 layers within a 4 layer printed circuit board, and can be applied to the manufacturing and processing of vias and/or microvias in any number of layers of a printed circuit board. In addition, the method and process as described herein can be used in the formation of two more vias or microvias, which form a stack having equal and/or different diameters.

It will be apparent to those skilled in the art that various modifications and variation can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming vias in a multilayered printed circuit board comprising:
providing a multilayered printed circuit board having at least two or more layers;
placing a donut pad on an upper layer of at least one layer of the multilayered printed circuit board for forming a via through one or more of the layers of the multilayered printed circuit board, the donut pad having a clearance of less than approximately 80 to 90 percent of a diameter of the via; and
forming at least one via through the donut pad and at least one or more layers of the multilayered printed circuit board.

2. The method of claim 1, wherein the donut pad has a clearance of approximately 60 percent or less of the diameter of via.

3. The method of claim 1, comprising:
placing a capture pad on a lower surface of the at least one or more layers of the multilayered printed circuit board, and wherein the capture pad is located on a lower surface of the at least one via.

4. The method of claim 1, comprising:
using a YAG laser, a CO₂ laser, or a UV laser for forming the at least one via.

5. The method of claim 4, wherein the donut pad has an outer diameter of approximately 0.008 inches and an inner diameter of no greater than approximately 0.003 inches.

6. The method of claim 1, wherein the via is a microvia.

7. The method of claim 1, wherein the multilayered printed circuit board includes a multilayered laminate formed by the steps of:
providing at least one two-sided copper-clad laminate;
etching circuitry on each of the two-sides of the at least one two-sided copper-clad laminate;
placing the donut pad on an upper layer of the at least one two-sided copper-clad laminate;
placing a copper capture pad on a lower layer of the at least one two-sided copper-clad laminate;
laminating a top and a bottom prepreg layer on the two-sided copper-clad laminate; and
laminating a copper foil layer on the top and bottom prepreg layers.

8. The method of claim 7, comprising:
performing the laminating of the multilayered printed circuit board by placing the two-sided laminate, the top and bottom prepreg layer and the copper foils layers in a press and applying pressure and heat for a period of time.

9. The method of claim 8, comprising:
forming the at least one via in the multilayered printed circuit board after lamination;
placing an electroless copper layer on the capture pad and an inner wall of the at least one via;
placing an electroplated copper layer on the capture pad and the inner wall of the at least one via; and
filling the at least one via with copper.

10. The method of claim 1, wherein the donut pad is made of copper.

11. The method of claim 1, wherein the diameter of the via is equal to a diameter of a hole being drilled by a laser.

12. A method for forming vias in a multilayered printed circuit board comprising:
providing a multilayered printed circuit board comprising at least three dielectric layers, and at least two patterned circuit layer, and wherein each of the at least two patterned circuit layers are disposed between a pair of dielectric layers, and wherein at least one of the patterned circuit layers includes at least one capture pad;
placing a donut pad on an upper layer of at least of the patterned circuit layers; and
forming at least one via through the donut pad and a dielectric layer to the at least one capture pad;
wherein the donut pad has a clearance of less than approximately 80 to 90 percent of a diameter of the at least one via.

13. The method of claim 12, wherein the donut pad has a clearance of approximately 60 percent or less of the diameter of via.

14. A printed circuit board formed by the following process:
providing a multilayered printed circuit board comprising at least three dielectric layers, and at least two patterned circuit layer, and wherein each of the at least two patterned circuit layers are disposed between a pair of dielectric layers, and wherein at least one of the patterned circuit layers includes at least one capture pad;
placing a donut pad on an upper layer of at least of the patterned circuit layers; and
forming at least one via through the donut pad and a dielectric layer to the at least one capture pad;
wherein the donut pad having a clearance of less than approximately 80 to 90 percent of a diameter of the via.

15. The printed circuit board of claim 14, wherein the donut pad has a clearance of approximately 60 percent or less of the diameter of via.

16. The printed circuit board of claim 14, wherein the multilayered printed circuit board comprises a multilayered laminate formed by the steps of:
providing at least one two-sided copper-clad laminate;
etching circuitry on each of the two-sides of the at least one two-sided copper-clad laminate;
placing the donut pad on an upper layer of the at least one two-sided copper-clad laminate;
placing a copper capture pad on a lower layer of the at least one two-sided copper-clad laminate;
laminating a top and a bottom prepreg layer on the two-sided copper-clad laminate; and
laminating a copper foil layer on the top and bottom prepreg layers.

17. The printed circuit board of claim 16, comprising:
performing the laminating of the multilayered printed circuit board by placing the two-sided laminate, the top and bottom prepreg layer and the copper foils layers in a press and applying pressure and heat for a period of time.

18. The printed circuit board of claim 17, comprising:
forming the at least one via in the multilayered printed circuit board after lamination;
placing an electroless copper layer on the capture pad and an inner wall of the at least one via;
placing an electroplated copper layer on the capture pad and the inner wall of the at least one via; and
filling the at least one via with copper.
